(19) United States
(12) Patent Application Publication
(10) Pub. No.: US 2017/0291848 A1
(43) Pub. Date: Oct. 12, 2017

(54) ANNEALING METHOD USING FLASH LAMPS

(71) Applicant: SAINT-GOBAIN GLASS FRANCE, Courbevoie (FR)

(72) Inventors: Lorenzo CANOVA, Paris (FR); Emmanuel MIMOUN, Boulogne-Biiancourt (FR); Brice DUBOST, Courbevoie (FR)

(73) Assignee: SAINT-GOBAIN GLASS FRANCE, Courbevoie (FR)

(21) Appl. No.: 15/507,883

(22) PCT Filed: Aug. 20, 2015
(86) PCT No.: PCT/FR2015/052238

§ 371 Date: Mar. 1, 2017

(30) Foreign Application Priority Data
Sep. 11, 2014 (FR) 1458520

(51) Int. Cl. C03C 17/36; C03C 17/06; C23C 14/58; C03C 23/00

(52) U.S. Cl. CPC C03C 17/366; C03C 23/0005; C03C 17/06; C23C 14/5806; C03C 2218/32; C03C 2217/256

(57) ABSTRACT

A process that anneals a surface of a substrate bearing a coating includes running the substrate under a flash lamp emitting intense pulsed light and irradiating the coating with the pulsed light through a mask located between the flash lamp and the coating. A frequency of the flash lamp and a run speed of the substrate are adjusted so that each point of the coating to be annealed receives at least one light pulse. A distance between a lower face of the mask and the surface of the coating to be annealed is at most equal to 1 mm. A shape and extent of a slit in the mask are such that the mask occults the coating to be annealed in all zones where the light intensity that, in an absence of the mask, would arrive at the coating to be annealed is lower than a threshold light intensity.

The present invention relates to a process and an apparatus for rapid annealing thin films deposited on flat substrates, by means of flash lamps.

It is known to carry out local and rapid laser annealing (laser flash heating) of thin coatings deposited on flat substrates. To do this, the substrate with the coating to be annealed is made to run under a laser line, or instead a laser line is made to run over the substrate bearing the coating (see for example WO2008/096089 and WO 2013/156721).

The laser annealing allows thin coatings to be heated to high temperatures, of about several hundred degrees, while preserving the underlying substrate.

More recently it has been proposed to replace in such a surface annealing process the sources of laser light, such as laser diodes, with lamps producing intense pulsed light (IPL) also referred to as flash lamps. International patent application WO 2013/026817 thus provides a process for manufacturing a low-E coating comprising a step of depositing a thin silver-based film, then a step of rapid surface annealing of said film with the aim of decreasing its emissivity and increasing its conductivity. For the annealing step, the substrate coated with the silver film is made to run under an array of flash lamps downstream of the station for depositing the film.

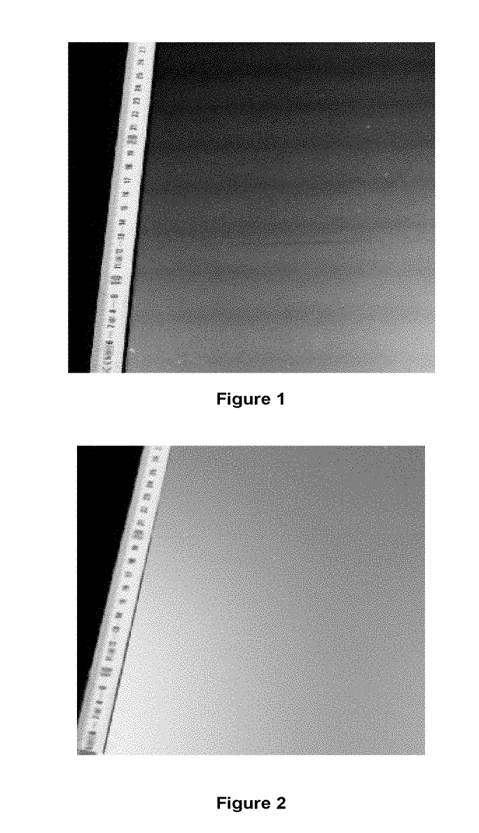

On attempting to reproduce this process with a Planitherm ONE® glazing pane (clear glass coated with a multilayer of thin transparent films, certain films of which are made of noble metals, deposited by vacuum sputtering), the Applicant observed nonuniformities in the appearance of the coating after annealing. FIG. 1 shows a Planitherm ONE® coating after annealing with flash lamps under the following conditions:

Intensity of each light pulse: 35 J/cm²

Duration of each light pulse: 2.7 ms

Frequency of the pulses: 0.5 Hz

Run speed of the substrate: 0.78 m/min

Approximate width of the zone illuminated by the lamp in the run direction of the substrate: 10 cm

Distance between the flash lamp and the substrate: 20 mm

Periodic striations were observed, separated by about 2.6 cm, which were absent from the coating directly after the deposition of the Planitherme® ONE multilayer.

Neither do these striations appear when the anneal of the coating is carried out by making an identical substrate run under a laser line generated by laser diodes. The appearance of the visible uniformity defects therefore seems to be related to the use of a pulsed light source (flash lamp) instead of a continuous light source (laser diode).

After many trials aiming to better understand this undesirable effect, the Applicant has found a solution that is fairly simple to implement and that allows this periodic uniformity defect in the annealed substrate to be considerably reduced or even completely suppressed.

This solution consists in interposing an opaque mask comprising an irradiation slit between the flash lamp and the coating to be annealed. In order for the use of such a mask to lead to the reduction or suppression of uniformity defects in the annealed coating, the following conditions must be met:
The mask and the irradiation slit must have a fixed position relative to the flash lamp;
The frequency of the flash lamp and the run speed of the substrate must be such that each point of the coating receives at least one light pulse;
The mask must be positioned as close as possible to the surface of the coating to be annealed, at the very most a few millimeters therefrom; and
The shape and extent of the irradiation slit must be such that the mask intercepts the light from the lamp, i.e. occults the substrate, in all the zones where the light intensity is lower than a threshold light intensity, called the nominal light intensity below.

In the present application, the expression “nominal light intensity” is understood to mean the intensity of a light pulse, of given duration, above which a second pulse of an intensity higher than or equal to that of the first pulse, and of the same duration, does not lead to the color in reflection of the coating changing.

A color change is the difference (ΔE*) between two colors

ΔE*=\sqrt{(L₁−L₂)²+(a₁−a₂)²+(b₁−b₂)²}

such as defined by the CIE L*a*b* (illuminant D65) color system. The

CIELab system defines a sphere-shaped color space with an L* axis characterizing lightness, a red/green a* axis and a blue/yellow b* axis. An a* value higher than 0 corresponds to hues with a red component, a negative a* value to hues with a green component, a positive b* value to hues with a yellow component and a negative b* value to hues with a blue component. In the above formula L₁, a₁ and b₁ are the coordinates in the CIELab color space of the first color and L₂, a₂ and b₂ those of the second.

When the coating to be annealed is irradiated with a first pulse of sufficient intensity, this irradiation provokes a change of the color of the coating (ΔE*₁). Then, when the same irradiation is repeated with a pulse of the same energy (same intensity and same duration), the additional color change provoked leads to a total color change (ΔE*₂).

When ΔE₂ is substantially equal to ΔE₁, i.e. when ΔE₂-ΔE₁ is lower than or equal to 1, the second pulse is considered not to have a significant incidence on the color of the coating and the intensity of the pulse is considered to be higher than or equal to the nominal intensity such as defined above.

In contrast, when the second pulse provokes a significant color change (ΔE*₂−ΔE*₁>1), the second pulse is considered to have an incidence on the color of the coating and the light intensity is considered to be lower than the nominal light intensity.

The light intensities to be considered are of course those measured level with the working plane, i.e. level with the coating to be annealed.

The light emitted by the flash lamp has, level with the working plane, a light intensity profile, also referred to as power density profile, at least one zone where the light intensity is higher than or equal to the nominal intensity such as defined above, and other zones, generally on the periphery of the irradiated zone, where the light intensity is lower than the nominal light intensity.

The irradiation mask must be positioned between the lamp and the coating so as to intercept all of the light that, level with the coating to be annealed, has a light intensity lower than the nominal intensity. The mask may optionally intercept a small portion of the light that has an intensity higher than or equal to the nominal intensity.

One subject of the present invention is a process for annealing the surface of a substrate bearing a coating, said process comprising:
running the substrate bearing the coating to be annealed under a flash lamp emitting intense pulsed light, that face of the substrate which bears said coating being turned toward the flash lamp; and
irradiating the coating to be annealed with the intense pulsed light emitted by the flash lamp through a mask located, in a fixed position relative to the flash lamp, between the flash lamp and the coating to be annealed and comprising a slit the longitudinal axis of which is perpendicular to the run direction of the substrate, the frequency of the flash lamp and the run speed of the substrate being adjusted so that each point of the coating to be annealed receives at least one light pulse;
   characterized in that
   the distance between the lower face of the mask and the surface of the coating to be annealed is at most equal to 1 mm, preferably at most equal to 500 μm and ideally at most equal to 100 μm,
   and in that the shape and extent of the slit are such that the mask occults the coating to be annealed in all the zones where the light intensity that, in the absence of the mask, would arrive at the coating to be annealed is lower than a threshold light intensity called hereafter “nominal light intensity”.

Each time a “flash lamp” is mentioned in the present application, this term designates a single flash lamp or an array of flash lamps, for example 5 to 20 lamps, or even 8 to 15 lamps, preferably placed parallel to one another and associated with one or more mirrors. Such an array of flash lamps and mirrors is for example used in the process disclosed in WO 2013/026817. The function of the mirrors is to direct all the light emitted by the lamps in the direction of the substrate and to confer on the light intensity profile a desired truncated bell shape having an almost constant central intensity plateau (varying by less than 5%) and lateral flanks where the intensity gradually decreases. These mirrors may be flat mirrors or focusing mirrors.

The flash lamps used in the present invention generally are sealed glass or quartz tubes filled with a rare gas and equipped with electrodes at their ends. Under the effect of a short-duration electrical pulse obtained by discharging a capacitor, the gas ionizes and produces a pulse of particularly intense incoherent light. The emission spectrum generally comprises at least two emission lines; it is preferably a question of a continuous spectrum having an emission maximum in the near ultraviolet.

The lamp is preferably a xenon lamp. It may also be an argon lamp, a helium lamp or a krypton lamp. The emission spectrum preferably comprises a plurality of lines, especially at wavelengths ranging from 160 to 1000 nm.

The duration of the light pulse (flash) is preferably comprised in a range extending from 0.05 to 20 milliseconds and especially from 0.1 to 5 milliseconds. The repetition rate (frequency) is preferably comprised in a range extending from 0.1 to 5 Hz and especially from 0.2 to 2 Hz.

The lamp, or lamps, is (are) preferably placed transversely to the longest sides of the substrate. It possesses a length preferably of at least 1 m, especially of at least 2 m and even of at least 3 m, so as to allow large substrates to be treated.

The capacitor is typically charged to a voltage of 500 V to 500 kV. The current density is preferably at least 4000 A/cm². The total energy density emitted by the flash lamps, divided by the area of the coating, is preferably comprised between 1 and 100 J/cm², preferably between 2 and 30 J/cm² and in particular between 5 and 20 J/cm².

The substrate bearing the coating to be annealed is preferably made of glass or glass-ceramic. It is preferably transparent, colorless (clear or extra-clear glass) or tinted, for example blue, gray, green or bronze. The glass is preferably soda-lime-silica glass, but it may also be made of borosilicate or alumino-borosilicate glass. The substrate advantageously possesses at least one dimension larger than or equal to 1 m, or even 2 m and even 3 m. The thickness of the substrate generally varies between 0.1 mm and 19 mm, preferably between 0.7 and 9 mm, especially between 1 and 6 mm, or even between 2 and 4 mm.

The material of the coating to be annealed may in principle be any organic or mineral material that is not destroyed by the surface annealing is treatment and the physical properties, and especially color, of which are modified following this treatment.

It is preferably a mineral coating and in particular a coating comprising one or more films of a metal oxide and/or one or more films of a metal, preferably a noble metal, in the metal state.

In one embodiment, the coating to be annealed preferably comprises at least one film of a transparent conductive oxide (TCO). This oxide is preferably chosen from indium tin oxide (ITO), indium zinc oxide (IZO), fluorine- or antimony-doped tin oxide (FTO and ATO), zinc oxide doped with aluminum (AZO) and/or gallium (GZO) and/or titanium, titanium oxide doped with niobium and/or tantalum, and zinc or cadmium stannate.

One particularly preferred oxide is indium tin oxide, frequently called ITO. The atomic percentage of Sn is preferably comprised in a range extending from 5 to 70%, especially from 6 to 60% and advantageously from 8 to 12%. Relative to other conductive oxides, such as fluorine-doped tin oxide, ITO is appreciated for its high electrical conductivity, permitting the use of small thicknesses to obtain a good emissivity or resistivity level.

In another embodiment, the coating to be annealed comprises one or more thin films of a metal, in particular of a noble metal, typically films based on silver or gold, and preferably at least one silver film.

The physical thickness of the coating to be annealed is advantageously at least equal to 30 nm and at most equal to 5000 nm and preferably comprised between 50 nm and 2000 nm.

In the process of the present invention, the substrate bearing the coating to be annealed is made to run under or in front of flash lamps partially masked by the irradiation mask.

In order to increase the energy efficiency of the process, the flash lamps are preferably close to the coating to be annealed and advantageously located at less than 20 cm, preferably at less than 10 cm and in particular at less than 5 cm. The smaller this distance, the higher the light intensity level with the working plane (coating to be annealed) for a given operating power.

The irradiation mask comprises a slit the longitudinal axis of which is perpendicular to the run direction of the substrate. The simplest slit shape guaranteeing uniform irradiation of the coating to be annealed is a rectangle. The slit therefore preferably has a substantially rectangular shape. More complex but less preferable shapes are however also envisionable and the invention is not limited to the embodiment where the slit is a rectangle. A slit having an arc shape, a zigzag shape or a wavy shape would be equivalent to a rectangular slit provided that the upstream edge and the downstream edge of the slit remain parallel, allowing perfect juxtaposition (without gaps) of the irradiation zones corresponding to the successive light pulses.

The substrate bearing the coating to be annealed may be given its run movement using any appropriate mechanical conveying means, for example using belts, rollers and/or translational trays. The conveying system allows the speed of the movement to be controlled and adjusted.

The run speed of the substrate must be adjusted depending on the frequency of the pulses and the width of the slit in the mask so that each point of the coating receives at least one light pulse; in other words the run speed must be lower than or equal to the ratio L/P of the width of the slit (L) to the period (P) separating two pulses.

For an irradiation frequency of 1 Hz and a slit width of 10 cm, the run speed of the substrate must thus be at most 10 cm/second. When the run speed of the substrate is lower than L/P, a certain number of points receive two light pulses (zone of overlap), and this is not very advantageous from the point of view of the energy efficiency of the process. However, the existence of a relatively narrow zone of overlap guarantees the continuity of the irradiated zone in case of small variations in the run speed.

Therefore, in one preferred embodiment of the process of the present invention the frequency of the flash lamp, the width of the slit and the run speed of the substrate are such that at least 90%, preferably at least 95% and more preferably at least 98% of the points of the coating to be annealed receive only a single light pulse. In other words, at most 10%, is preferably at most 5% and more preferably at most 2% of the points of the coating receive two light pulses.

The run speed of the substrate is therefore preferably comprised between L/P and 0.9 L/P.

The run speed of the substrate bearing the coating to be annealed is advantageously comprised between 0.1 and 30 m/minute, preferably between 1 and 20 m/minute, and in particular between 2 and 10 m/minute.

The width of the irradiation slit is advantageously comprised between 1 and 50 cm and preferably between 5 and 20 cm.

The length of the slit is substantially equal to the width of the coating to be annealed, namely generally at least equal to 1 m, preferably at least equal to 2 m and in particular at least equal to 3 m.

As indicated above, the irradiation mask must be as close as possible to the coating to be annealed, i.e. the distance between its lower face and the surface of the coating to be annealed must not exceed 1 mm, preferably not exceed 500 μm and ideally is at most equal to 100 μm.

Of course, in a continuous process, where the substrate runs continuously under stationary lamps—or a lamp and a mask are continuously run relative to a stationary substrate—it is impossible to place the mask directly in contact with the coating to be annealed. It is indispensable, to adjust the distance between the mask and the coating to be annealed to allow for undulations in the surface of the substrate that are reproduced in the surface of the coating to be annealed.

It is therefore important to understand that there exists not only a maximum distance between the mask and the surface of the coating but also a minimum distance that must be enough to guarantee the absence of contact between the mask and the coating. This minimum distance of course depends on the flatness of the substrate and/or on the roughness of the coating. It may for example be 10 μm or 20 μm or even 50 μm.

Another subject of the present invention is an apparatus for annealing the surface of a substrate bearing a coating to be annealed, this apparatus being particularly appropriate for implementing the process of the present application.

The apparatus of the present invention comprises:
a flash lamp capable of emitting intense pulsed light;
a conveying means making it possible to make a flat substrate bearing a coating to be annealed run in front of the flash lamp; and
a mask located, in a fixed position relative to the flash lamp, between the flash lamp and the conveying means, said mask comprising a slit the longitudinal axis of which is perpendicular to the run direction of the substrate and being positioned so that the light emitted by the flash lamp is projected through the slit in the direction of the flat substrate bearing a coating to be annealed;
   and furthermore comprises means for adjusting the distance between the mask and the conveying means such that the distance between the lower face of the mask and the surface of the coating to be annealed is adjustable to a value lower than 1 mm, preferably lower than 500 μm and in particular lower than 100 μm.

The mask will preferably be made from a metal, typically aluminum or copper.

It will possibly be covered with an absorbent layer, or undergo an anodization treatment that makes it absorbent, in order to absorb any light that it intercepts. In this case, the body of the mask will preferably make contact with a cooling circuit, so as to keep its temperature below 100° C. and preferably below 50° C.

Another possibility is the use of a scattering reflective layer for the mask, so that the light intercepted is not absorbed but scattered in order to lower the reflected light intensity and therefore its dangerousness.

The thickness of the mask at the edges of the slit must be the smallest possible, preferably smaller than 500 μm or smaller than 200 μm or even smaller than 100 μm.

In order to ensure the mechanical rigidity of the mask and its cooling, the portions of the mask further away from the slit may be thicker.

The edges of the slit may thus be beveled, so that the light is intercepted by the thinnest portion.

The invention is explained in greater detail with reference to the figures.

FIG. 1 shows a photograph of a substrate bearing a Planitherme® ONE coating irradiated under the conditions such as indicated above in the absence of a mask. Periodic horizontal striations can be seen, spaced apart by about 2.6 cm.

FIG. 2 is a photograph of a Planitherme® ONE substrate treated according to the process of the invention. The striations visible in FIG. 1 have completely disappeared by virtue of the interposition of a mask under the conditions according to the invention.

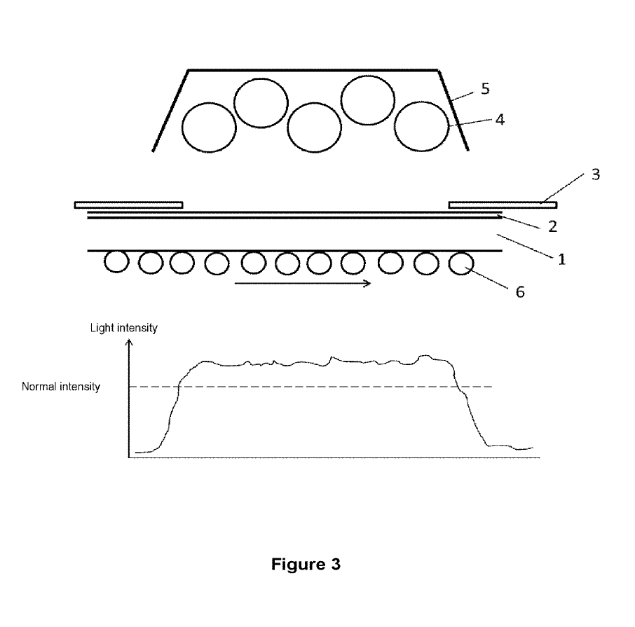

FIG. 3 is an explanatory schematic showing the operation of the process of the present invention and, more particularly, the appropriate position of the irradiation mask in relation to the light intensity profile of the lamps.

In this FIG. 3 a continuous flat substrate 1 bearing a coating 2 to be annealed is conveyed by rollers 6 in the run direction indicated by the arrow.

The coating 2 to be annealed is irradiated with light emitted by an array of lamps 4 and directed downward by means of a set of mirrors 5, through a mask 3. The distance between the two portions of the mask 3 corresponds to the width of the longitudinal slit.

The distance between the lower face of the mask 3 and the upper face of the coating 2 to be annealed is smaller than 1 mm.

In the bottom portion of the figure the intensity profile of a light pulse such as would exist level with the coating 2 to be annealed in the absence of the mask 3 is shown. The mask 3 is positioned such that light having an intensity lower than the nominal intensity is intercepted by the opaque zones of the mask.

1-9. (canceled)

10. A process for annealing a surface of a substrate bearing a coating, said process comprising:
running the substrate bearing the coating to be annealed under a flash lamp emitting intense pulsed light, the surface of the substrate that bears said coating being turned toward the flash lamp; and
irradiating the coating to be annealed with the intense pulsed light emitted by the flash lamp through a mask located, in a fixed position relative to the flash lamp, between the flash lamp and the coating to be annealed and comprising a slit, a longitudinal axis of the slit being perpendicular to a run direction of the substrate, a frequency of the flash lamp and a run speed of the substrate being adjusted so that each point of the coating to be annealed receives at least one light pulse,
wherein
a distance between a lower face of the mask and the surface of the coating to be annealed is at most equal to 1 mm, and
a shape and extent of the slit are such that the mask occults the coating to be annealed in all zones where the light intensity that, in an absence of the mask, would arrive at the coating to be annealed is lower than a threshold light intensity called a nominal light intensity.

11. The process as claimed in claim 10, wherein the distance between the lower face of the mask and the surface of the coating to be annealed is at most equal to 500 μm.

12. The process as claimed in claim 10, wherein the distance between the lower face of the mask and the surface of the coating to be annealed is at most equal to 100 μm.

13. The process as claimed in claim 10, wherein the slit has a substantially rectangular shape.

14. The process as claimed in claim 10, wherein the frequency of the flash lamp, a width of the slit, and the run speed of the substrate are such that at least 90% of the points of the coating to be annealed receive a single light pulse.

15. The process as claimed in claim 10, wherein a length of the slit is substantially equal to a width of the coating to be annealed.

16. The process as claimed in claim 10, wherein a width of the coating to be annealed is at least equal to 1 m.

17. The process as claimed in claim 10, wherein a width of the slit is between 1 and 50 cm.

18. The process as claimed in claim 10, wherein the run speed of the substrate bearing the coating to be annealed is between 0.1 and 30 m/minute.

19. The process as claimed in claim 10, wherein the coating to be annealed comprises at least one film of a metal.

20. The process as claimed in claim 19, wherein the at least one film of a metal includes a silver film.

21. The process as claimed in claim 10, wherein the coating to be annealed comprises at least one film of a transparent conductive oxide.

22. An apparatus for annealing a surface of a substrate bearing a coating, comprising:
a flash lamp configured to emit intense pulsed light;
conveying means for running a flat substrate bearing the coating to be annealed in front of the flash lamp;
a mask located, in a fixed position relative to the flash lamp, between the flash lamp and the conveying means, said mask comprising a slit, a longitudinal axis of the slit being perpendicular to a run direction of the substrate, and the slit being positioned so that the light emitted by the flash lamp is projected through the slit in a direction of the flat substrate bearing the coating to be annealed; and
means for adjusting a distance between the mask and the conveying means such that a distance between a lower face of the mask and the surface of the coating to be annealed is adjustable to a value lower than 1 mm.

23. The apparatus according to claim 22, wherein the distance between the lower face of the mask and the surface of the coating to be annealed is adjustable to a value lower than 500 μm.

24. The apparatus according to claim 22, wherein the distance between the lower face of the mask and the surface of the coating to be annealed is adjustable to a value lower than 100 μm.
